(19) United States
(12) Patent Application Publication
(10) Pub. No.: US 2017/0089968 A1
(43) Pub. Date: Mar. 30, 2017

(54) ANTENNA COMMUNICATION SYSTEM AND ANTENNA INTEGRATED SMART DEVICE THEREOF

(71) Applicant: SKY ALIGN SOLUTIONS PRIVATE LIMITED, Nerul (IN)

(72) Inventors: RAJESH SHANTARAM BAGUL, ULHASNAGAR (IN); SHARAD SRIWASTAVA, NERUL (IN)

(21) Appl. No.: 15/013,782

(22) Filed: Feb. 2, 2016

(30) Foreign Application Priority Data
Sep. 30, 2015 (IN) 3711/MUM/2015

(51) Int. Cl. G01R 29/10; H04W 72/04; H04M 15/00; H04W 24/02

(52) U.S. Cl. CPC G01R 29/10; H04W 24/02; H04W 72/046; H04M 15/58

(57) ABSTRACT

The present invention relates to an antenna communication system and antenna integrated smart device thereof. The device includes an antenna measurement unit, a microprocessor, a sensor unit, and an integrated internal camera. The antenna measurement unit is configured to determine a plurality of measurements associated with a plurality of antenna parameters of an antenna in a cell site. The antenna parameters include antenna azimuth, antenna tilt, antenna roll, antenna height and antenna geographical coordinates. The microprocessor is coupled to the antenna measurement unit and is configured to process the plurality of measurements to determine the plurality of antenna parameters. The sensor unit is coupled to the microprocessor and is configured to sense a plurality of environmental conditions around the cell site. The integrated internal camera is coupled to the microprocessor and is configured to capture a first set of images and a first set of videos around the cell site.

### CROSS REFERENCE TO RELATED APPLICATIONS

The present application claims priority to Indian patent application number 3711/MUM/2015 filed on 30 Sep. 2015, which is incorporated herein by reference.

### FIELD OF THE INVENTION

The present invention generally relates to antennas and more particularly to an antenna communication device and an antenna integrated smart device thereof.

BACKGROUND TO THE INVENTION

In a cellular telecommunication network, azimuth (or direction) and tilt values of an antenna determines a coverage area of a cell site (also referred to as a base station or cell tower). The azimuth and tilt values are typically derived from exhaustive computations. The antenna must then be installed precisely in a particular direction and be given a tilt according to the azimuth and tilt values, respectively, based on the computations. Orientation of the antenna changes over a period of time due to a continuous radio frequency (RF) optimization process. Further, changing demographics of the cell site, for example a new building, entails change in the azimuth and tilt values for optimized RF coverage and neighbour cell interference mitigation. In a present scenario, the azimuth and tilt values of the antenna are verified manually (by conducting periodic surveys) by a technician. The technician, typically, mounts a pole of the antenna, measures antenna orientation parameters (the azimuth and tilt values) and logs corresponding values, which is both tedious and time consuming. Moreover, there is a delay in such values reaching cellular operators, thereby causing a decrease in operation efficiency of the cellular communication network as well as a reduction of profits. Further, the technician or an RF engineer performs a naked eye observation from location of the antenna to understand clutter and demography of the cell site served by the antenna.

One solution to the above problems include an antenna alignment device that measures the azimuth and tilt values. However, the antenna alignment device is big in size and heavy in weight. Moreover, the antenna alignment device is used only during installation of the antenna and during surveys that are conducted every few months after the antenna is installed. In some other solutions, devices used are either handheld or stand mounted. Such devices usually do not provide accurate measurements and cannot be used to perform any extended functions.

### SUMMARY OF THE INVENTION

This summary is provided to introduce a selection of concepts in a simplified format that are further described in the detailed description of the invention. This summary is not intended to identify key or essential inventive concepts of the subject matter, nor is it intended for determining the scope of the invention.

In an embodiment, an antenna integrated smart device is disclosed. The antenna integrated smart device includes an antenna measurement unit, a microprocessor, a sensor unit, and an integrated internal camera. The antenna measurement unit is configured to determine a plurality of measurements associated with a plurality of antenna parameters of an antenna in a cell site. The plurality of antenna parameters include antenna azimuth, antenna tilt, antenna roll, antenna height and antenna geographical coordinates. The microprocessor is coupled to the antenna measurement unit and is configured to process the plurality of measurements to determine the plurality of antenna parameters. The sensor unit is coupled to the microprocessor and is configured to sense a plurality of environmental conditions around the cell site. The integrated internal camera is coupled to the microprocessor and is configured to capture a first set of images and a first set of videos around the cell site.

In another embodiment, an antenna communication system is disclosed. The antenna communication system includes at least one antenna integrated smart device, a cloud management server, and at least one user device. The at least one antenna integrated smart device is coupled to an antenna in a cell site to collect data associated with the antenna. The cloud management server is communicably coupled to the at least one antenna integrated smart device to receive and store the data from the at least one antenna integrated smart device. The cloud management server further processes the data to obtain processed data. The at least one user device is communicably coupled to the cloud management server to access the processed data.

In another embodiment, a method of accessing data of an antenna integrated smart device implemented in an antenna communication system is disclosed. The method includes receiving, by a cloud management server, the data associated with the antenna integrated smart device. The antenna integrated smart device is fixed on an antenna in a cell site. The data includes at least one of a plurality of measurements associated with a plurality of antenna parameters of the antenna, the antenna parameters, a plurality of environmental conditions around the cell site and a plurality of images and videos around the cell site. The method also includes processing, by the cloud management server, the data to obtain processed data and to generate business analytics. The method further includes enabling, by the cloud management server, one or more users to access the processed data and the business analytics using at least one user device.

To further clarify advantages and features of the present invention, a more particular description of the invention will be rendered by reference to specific embodiments thereof, which is illustrated in the appended figures. It is appreciated that these figures depict only typical embodiments of the invention and are therefore not to be considered limiting of its scope.

### BRIEF DESCRIPTION OF THE FIGURES

The invention will be described and explained with additional specificity and detail with the accompanying figures in which:

FIG. 1 is an example representation of an antenna communication system, in accordance with an embodiment;

FIG. 2 illustrates an antenna integrated smart device, in accordance with an embodiment;

FIG. 3 is an example representation of an antenna communication system, in accordance with another embodiment;

FIG. 4 illustrates an example flow diagram of a method of accessing data of an antenna integrated smart device implemented in an antenna communication system, in accordance with an embodiment; and

FIG. 5 illustrates a block diagram of an electronic device, in accordance with one embodiment.

Further, skilled artisans will appreciate that elements in the figures are illustrated for simplicity and may not have been necessarily been drawn to scale. Furthermore, in terms of the construction of the device, one or more components of the device may have been represented in the figures by conventional symbols, and the figures may show only those specific details that are pertinent to understanding the embodiments of the present invention so as not to obscure the figures with details that will be readily apparent to those of ordinary skill in the art having benefit of the description herein.

### DESCRIPTION OF THE INVENTION

For the purpose of promoting an understanding of the principles of the invention, reference will now be made to the embodiment illustrated in the figures and specific language will be used to describe the same. It will nevertheless be understood that no limitation of the scope of the invention is thereby intended, such alterations and further modifications in the illustrated system, and such further applications of the principles of the invention as illustrated therein being contemplated as would normally occur to one skilled in the art to which the invention relates.

It will be understood by those skilled in the art that the foregoing general description and the following detailed description are exemplary and explanatory of the invention and are not intended to be restrictive thereof.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components. Appearances of the phrase “in an embodiment”, “in another embodiment” and similar language throughout this specification may, but do not necessarily, all refer to the same embodiment.

Unless otherwise defined, all technical and scientific terms used herein have the same meaning as commonly understood by one of ordinary skill in the art to which this invention belongs. The system, methods, and examples provided herein are illustrative only and not intended to be limiting.

Embodiments of the present invention will be described below in detail with reference to the accompanying figures.

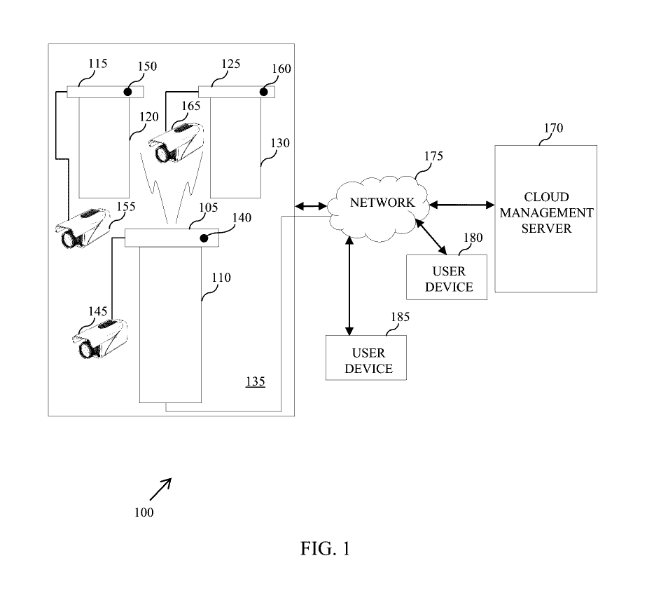

FIG. 1 is an example representation of an antenna communication system 100, in accordance with an embodiment. The antenna communication system 100 includes one or more antenna integrated smart devices placed atop corresponding antennas, for example an antenna integrated smart device 105 placed atop an antenna 110, an antenna integrated smart device 115 placed atop an antenna 120, and an antenna integrated smart device 125 placed atop an antenna 130. The antenna 110, the antenna 120, and the antenna 130 are included within a cell site (or cell tower) 135. The antenna integrated smart device 105, hereinafter referred to as the device 105, includes an integrated internal camera 140, hereinafter referred to as the camera 140. The device 105 is further shown to be coupled to an external camera 145, however it should be understood that the device 105 can be coupled to a plurality of external cameras. The antenna integrated smart device 115, hereinafter referred to as the device 115, includes an integrated internal camera 150, hereinafter referred to as the camera 150. The device 115 is further coupled to an external camera 155. The antenna integrated smart device 125, hereinafter referred to as the device 125, includes an integrated internal camera 160, hereinafter referred to as the camera 160. The device 125 is further coupled to an external camera 165. The device 105 is a master device and the device 115 and the device 125 are slave devices.

The antenna communication system 100 further includes a cloud management server 170, a network 175, and a plurality of user devices, for example a user device 180 and a user device 185. The device 105 atop the antenna 110 communicates with the cloud management server 170 through the network 175. The user device 180 and the user device 185 can communicate with the cloud management server 170 through the network 175. Examples of the plurality of user devices (the user device 180 and the user device 185) include, but are not limited to, computers, mobile devices, tablets, laptops, palmtops, handheld devices, telecommunication devices, personal digital assistants (PDAs), and the like. Examples of the network 175 includes, but are not limited to, Internet, a Local Area Network (LAN), a Wireless Local Area Network (WLAN), a Wide Area Network (WAN), internet, a Small Area Network (SAN), and the like.

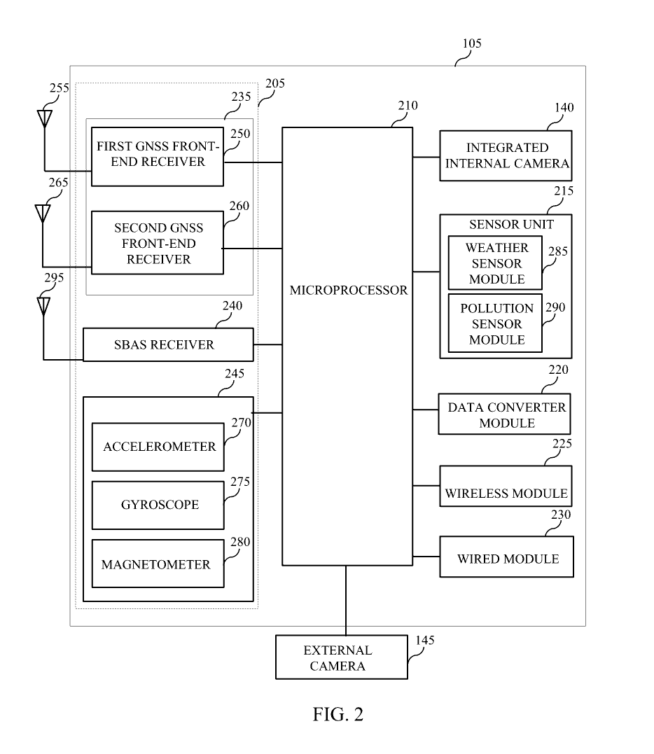

The device 105, the device 115, and the device 125, are configured to collect data associated with the antenna 110, the antenna 120, and the antenna 130, respectively. Examples of the data include, but are not limited to, a plurality of measurements associated with a plurality of antenna parameters, the antenna parameters, a plurality of environmental conditions around the cell site 135, a first set of images and a first set of videos around the cell site 135, and a second set of images and a second set of videos around the cell site 135. Examples of the antenna parameters include, but are not limited to, antenna azimuth, antenna tilt, antenna roll, antenna height and antenna geographical coordinates. Each integrated internal camera, for example the camera 140, the camera 150, or the camera 160, captures the first set of images and the first set of videos. Each external camera, for example the external camera 145, the external camera 155, or the external camera 165, captures the second set of images and the second set of videos. The data collected by the device 115 and the device 125 are transmitted to the device 105. The data from the device 105, the device 115, and the device 125 are then transmitted to the cloud management server 170 through the network 175. The cloud management server 170 can store the data and process the data to obtain processed data. The user device 180 and the user device 185 can access the processed data from the cloud management server 170. An example representation of an antenna integrated smart device, for example the device 105, is explained with reference to FIG. 2.

Referring now to FIG. 2, an antenna integrated smart device, for example the device 105 is illustrated, in accordance with an embodiment. The device 105 includes an antenna measurement unit 205, a microprocessor 210, a sensor unit 215, an integrated internal camera, for example the camera 140, a data converter module 220, a wireless module 225, and a wired module 230. The antenna measurement unit 205 includes a dual global navigation satellite system (GNSS) receiver 235, a satellite-based augmentation system (SBAS) receiver 240, and an inertial Micro Electro-Mechanical System (MEMS) system 245. The dual GNSS receiver 235 includes a first GNSS front-end receiver 250 coupled to a first antenna 255, and a second GNSS front-end receiver 260 coupled to a second antenna 265. The first antenna 255 and the second antenna 265 are separated by a predetermined distance, for example by 30 centimetres. The first antenna 255 and the second antenna 265 are GNSS antennas. The inertial MEMS system 245 includes an accelerometer 270, a gyroscope 275, and a magnetometer 280. The sensor unit 215 includes a weather sensor module 285 and a pollution sensor module 290. One or more external cameras, for example the external camera 145, is coupled to the device 105. The antenna measurement unit 205, the sensor unit 215, the camera 140, the data converter module 220, the wireless module 225, and the wired module 230 are coupled to the microprocessor 210.

The antenna measurement unit 205 is configured to determine a plurality of measurements associated with the plurality of antenna parameters (for example, the antenna azimuth, antenna tilt, antenna roll, antenna height and antenna geographical coordinates) of the antenna 110 in the cell site 135. The first antenna 255 and the second antenna 265 each receive GNSS analog signals from satellites (1 to M), for example three or four satellites, in space. The first GNSS front-end receiver 250 and the second GNSS front-end receiver 260 are radio frequency (RF) front-end receivers. Each GNSS front-end receiver typically includes a surface acoustic wave (SAW) filter, a low noise amplifier to amplify the GNSS analog signals, a down converter to down convert the amplified GNSS analog signals, and an analog to digital converter to digitize the amplified and down converted GNSS analog signals. The first GNSS front-end receiver 250 and the second GNSS front-end receiver 260 convert the GNSS analog signals into GNSS digital signals. The GNSS digital signals are further transmitted to the microprocessor 210. In an example, the microprocessor 210 is a digital signal processor (DSP).

The SBAS receiver 240 is an RF receiver and is coupled to an antenna 295. In an example, the SBAS receiver 240 is used to correct satellite orbit errors, ionospheric errors and tropospheric errors. The antenna 295 receives SBAS analog signals. The SBAS receiver 240 further converts the SBAS analog signals into SBAS digital signals. The SBAS digital signals are further transmitted to the microprocessor 210 for SBAS message decoding. In some embodiments, the first GNSS front-end receiver 250 and the second GNSS front-end receiver 260 perform functions of the SBAS receiver 240.

The inertial MEMS system 245 is configured to determine measurement values of the antenna azimuth and the antenna tilt. The accelerometer 270, the gyroscope 275, and the magnetometer 280 are used to determine the measurement values of the antenna azimuth and the antenna tilt. The accelerometer 270 is configured to measure inertial acceleration of the antenna 110. The gyroscope 275 is configured to detect changes in one or more rotational attributes of the antenna 110. Examples of the one or more rotational attributes include, but are not limited to, pitch, roll, and yaw. The magnetometer 280 is configured to determine dynamic orientation of the antenna 110. During cases of GNSS outage, the device 105 uses the measurement values of the antenna azimuth and the antenna tilt as the antenna parameters. During cases of acceptable GNSS reception, the device 105 determines true values of the antenna azimuth and the antenna tilt based on performing filtering. The filtering is performed on measurement values determined by the dual GNSS receiver 235 as well as the measurement values of the antenna azimuth and the antenna tilt determined by the inertial MEMS system 245.

The sensor unit 215 is configured to sense a plurality of environmental conditions around the cell site. The weather sensor module 285 includes a plurality of weather sensors and is configured to sense a plurality of weather conditions around the cell site 135. Examples of the weather conditions include, but are not limited to, temperature, humidity, air pressure, rainfall. The pollution sensor module 290 is configured to sense a plurality of pollution levels around the cell site 135. In an example, the pollution sensor module 290 includes a carbon dioxide sensor and a carbon monoxide sensor to determine pollution levels of carbon dioxide and carbon monoxide, respectively. Values determined by the weather sensor module 285 and the pollution sensor module 290 are transmitted to the microprocessor 210.

The data converter module 220 is configured to convert data into encrypted data and convert the encrypted data into decrypted data. In an example, the data converter module 220 includes an encryption module for encrypting the data into the encrypted data, and a decryption module for decrypting the encrypted data into decrypted data. In an example, the data includes data being transmitted from the device 105 to the cloud management server 170. The wireless module 225 is configured to exchange the data wirelessly. In an example, the wireless module 225 includes at least one of a wireless fidelity (WiFi) module and a Bluetooth module. The device 105, being the master device, uses the wireless module 225 to exchange the data wirelessly (using WiFi or Bluetooth) with the slave devices, for example the device 115 and the device 125 of FIG. 1. In another example, the user device 185 can communicate with the device 105 directly if present in vicinity of the device 105 and if configured to do so through the wireless module 225. The wired module 230 is configured to exchange the data through wired connections. In an example, the wired module 230 includes an Ethernet switch.

The camera 140 is configured to capture a first set of images and a first set of videos around the cell site 135. As the camera 140 is integrated within the device 105, the first set of images and the first set of videos are captured from one angle. The first set of images and the first set of videos can be transmitted to the cloud management server 170 on demand. In an example, the first set of videos are live videos that are streamed from the camera 140 to the cloud management server 170. The external camera 145, one of multiple external cameras, is configured to capture a second set of images and a second set of videos around the cell site 135. The external camera 145 is usually located at some distance from the device 105, thereby capturing the second set of images and the second set of videos from a different angle. The second set of images and the second set of videos can be transmitted to the cloud management server 170 on demand. In an example, the external camera 145 can be powered by power over Ethernet (PoE). In an example, the external camera 145 is coupled to the device 105 by electrical or optical Ethernet connection.

The microprocessor 210 is configured to process the plurality of measurements to determine the plurality of antenna parameters. An example of the microprocessor 210 is an ARM based microprocessor running a Linux operating system. The microprocessor 210 decodes GNSS messages, calculates carrier phase and resolves integer ambiguity during determination of the antenna parameters. In an example, the microprocessor 210 includes two GNSS decoders for decoding the GNSS messages. The microprocessor 210 uses a combination of precise differential GNSS positioning, extended kalman filtering and sphere decoding techniques to accurately determine GNSS co-ordinates of the location of the first antenna 255 and the second antenna 265. On determining the GNSS co-ordinates of the first antenna 255 and the second antenna 265 and priori information on distance between the first antenna 255 and the second antenna 265 (for example, 30 centimetres), the antenna azimuth is determined by the microprocessor 210. In an example, accuracy of the antenna azimuth is ±0.3 degrees root mean square (RMS), of the antenna tilt is ±0.25 degrees, of the antenna height is ±0.3 metres, of the antenna roll is ±0.25 degrees, and of the antenna geographical coordinates coordinates is ±1 centimetres.

The microprocessor 210 further includes an SBAS decoder that receives the SBAS digital signals from the SBAS receiver 240. In an example, the SBAS decoder is implemented as a software running on the microprocessor 210. The SBAS decoder determines satellite orbital errors, ionospheric errors and tropospheric errors to improve position accuracy of the GNSS co-ordinates of the first antenna 255 and the second antenna 265 to less than one centimetre.

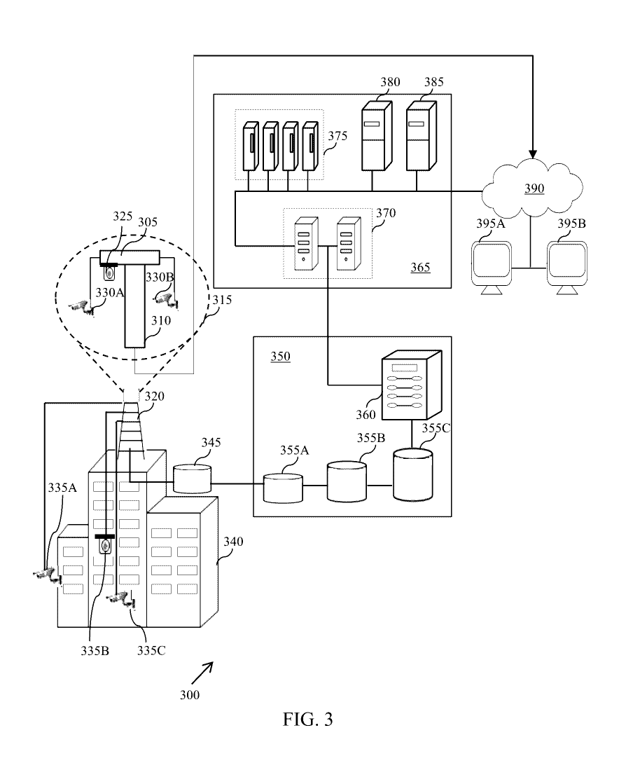

The microprocessor 210 is further configured to communicate with the cloud management server 170 over a message based protocol. For example, keep alive messages are transmitted by the microprocessor 210 to inform the cloud management server 170 regarding working status of the device 105. The microprocessor 210 further collects the antenna azimuth, the antenna tilt, the antenna roll, the antenna height and the antenna geographical coordinates, the weather conditions and the pollution levels from corresponding modules and transmits the data to the cloud management server 170 either periodically or when commanded by the cloud management server 170. In an example, a control plane software is used in the microprocessor 210 to perform such communication with the cloud management server 170. Another example representation of an antenna communication system is explained with reference to FIG. 3.

FIG. 3 is an example representation of an antenna communication system 300, in accordance with another embodiment. The antenna communication system 300 includes one or more antenna integrated smart devices placed atop corresponding antennas, for example an antenna integrated smart device 305 placed atop an antenna 310 (illustrated as an exploded view 315) within a cell site 320 (also referred to as a cell tower or base station). The antenna integrated smart device 305, hereinafter referred to as the device 305, includes an integrated internal camera 325, hereinafter referred to as the camera 325. The device 305 is further coupled to an external camera 330A and an external camera 330B. The device 305 is further configured to be coupled to other external devices, for example an external camera 335A, an external camera 335B, and an external camera 335C. The external camera 335A, the external camera 335B, and the external camera 335C are located within a building 340 on top of which the cell site 320 is placed. The device 305 is a master device and other devices within the cell site 320 are slave devices that communicate data to the device 305.

The cell site 320 is further coupled to a cell site router 345 that routes data from multiple cell sites. The cell site router 345 is coupled to a transport network 350 including multiple aggregation routers, for example an aggregation router 355A, an aggregation router 355B, and an aggregation router 355C. The cell site router 345 is coupled to the aggregation router 355A. The aggregation router 355B is coupled between the aggregation router 355A and the aggregation router 355C. The aggregation router 355C is further coupled to a service aggregation router 360. The aggregation routers and the service aggregation routers further route the data to a cloud management server 365 in the antenna communication system 300. The cloud management server 365 is a big data platform that is implemented in form of multiple servers hosted in a cloud to process the data from the device 305 to obtain processed data. Determination and collection of the data of the device 305 is similar to that of the device 105 of FIG. 2 and is not explained herein for sake of brevity.

The cloud management server 365 includes a media server unit 370, a storage area network 375, an authentication server 380, and an image processing and business analytics server 385. The media server unit 370 can include one or more servers that stores a first set of images and a first set of videos captured by the camera 325. The media server unit 370 further stores a second set of images and a second set of videos captured by the external camera 330A, the external camera 330B, the external camera 335A, the external camera 335B, and the external camera 335C. The storage area network 375 is used to store the data being transmitted from the device 305 to a network 390, for example Internet. Examples of the data include, but are not limited to, a plurality of measurements associated with a plurality of antenna parameters, the antenna parameters, weather conditions around the cell site 320, the first set of images and the first set of videos around the cell site 320, and the second set of images and the second set of videos around the cell site 320. The authentication server 380 (also referred to as an operation server or an authorization server) is used to authenticate the device 305 and the data received from the device 305, and to perform one or more operations on the data.

The image processing and business analytics server 385 further performs image processing on the first set of images and the first set of videos, the second set of images, and the second set of videos. Business analytics are further generated based on the data (the images) to optimize business processes, security processes, and the like. In an example, the business analytics that can be generated include identifying number of people in a given area (also referred to as footfall), identifying amount of time spent by a person at a given location (also referred to as dwell time) using a spot path map based on a thermal map (as the camera 325 includes a thermal sensor). In other examples, the business analytics that can be generated include restricting people movement in a given perimeter (also referred to as fencing) and raising an alarm in case of violation. The business analytics can further include detection of a person, car registration number, break in and break out, and missing object detection in law enforcement. In other examples, the business analytics that can be generated include detection of gender to provide data on number of men and women in a given area, reporting traffic congestion, and understanding traffic patterns.

The antenna communication system 300 further includes a user device 395A and a user device 395B. The user device 395A and the user device 395B are used by associated users to access the processed data and the business analytics of the cloud management server 365. For example, if a user of the user device 395A, for example a smartphone, wants to view images (the first set of images) captured by the camera 325 of the device 305, the user can open a related mobile application in the user device 395A and view the images. In an example, the mobile application can use a function based display to display the processed data to the user. In an example, the images can be retrieved by sending a request to the media server unit 370 located in the cloud management server 365. In another example, the user of the user device 395A can directly communicate with the device 305 over WiFi or Bluetooth when nearby the cell site 320 and view the antenna parameters including antenna azimuth, antenna tilt, antenna roll, antenna height and antenna geographical coordinates. The user can further view images and videos captured by the camera 325 on the user device 395A. In some embodiments, the user of the user device 395A (or the user device 395B) can configure the device 305 using the mobile application with right user access privileges.

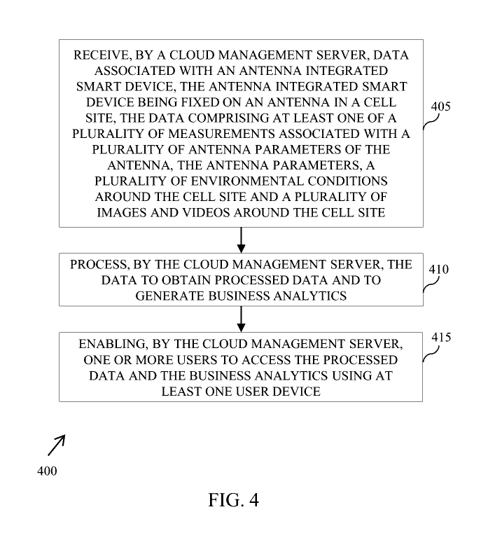

The above steps are explained with respect to a single antenna integrated smart device, for example the device 120. However, it should be noted that the above steps can be similarly applied to other antenna integrated smart devices. An example method of accessing the data of an antenna integrated smart device, for example the device 105 or the device 305, implemented in an antenna communication system is explained with reference to FIG. 4.

FIG. 4 illustrates an example flow diagram of a method 400 of accessing data of an antenna integrated smart device, for example the device 105 of FIG. 1 or the device 305 of FIG. 3, implemented in an antenna communication system, for example the antenna communication system 100 of FIG. 1 or the antenna communication system 300 of FIG. 3, in accordance with an embodiment. At step 405, the method 400 includes receiving the data associated with the antenna integrated smart device, hereinafter referred to as the device. The data is received by a cloud management server, for example the cloud management server 170 of FIG. 1 or the cloud management server 365 of FIG. 3. The device is fixed on an antenna, for example the antenna 110 of FIG. 1 or the antenna 310 of FIG. 3, in a cell site, for example the cell site 135 of FIG. 1 or the cell site 320 of FIG. 3, usually at a top position on the antenna. Examples of the data includes, but is not limited to, at least one of a plurality of measurements associated with a plurality of antenna parameters of the antenna, the antenna parameters, a plurality of environmental conditions around the cell site and a plurality of images and videos around the cell site.

The plurality of measurements is determined by an antenna measurement unit, for example the antenna measurement unit 205 of FIG. 2, of the antenna integrated smart device. The antenna parameters is determined by a microprocessor, for example the microprocessor 210 of FIG. 2, of the antenna integrated smart device. The plurality of environmental conditions is determined by a sensor unit, for example the sensor unit 215 of FIG. 2, of the antenna integrated smart device. The plurality of images and videos is determined by at least one of an integrated internal camera, for example the camera 140 of FIG. 2, of the antenna integrated smart device and one or more external cameras, for example the external camera 145 of FIG. 2, coupled to the antenna integrated smart device. The method of determining the data is explained with reference to FIG. 2 and is not explained herein for sake of brevity.

At step 410, the method 400 includes processing the data to obtain processed data and to generate business analytics. The data is processed by the cloud management server. The method of processing the data and generating the business analytics using one or more servers in the cloud management server is explained with reference to FIG. 2 and is not explained herein for sake of brevity.

At step 415, the method 400 includes enabling one or more users to access the processed data and the business analytics using at least one user device, for example the user device 180 or the user device 185 of FIG. 1, or the user device 395A or the user device 395B of FIG. 3. The processed data and the business analytics can be accessed by a user though a mobile application installed on a user device, for example the user device. The method of enabling the one or more users to access the processed data and the business analytics is explained with reference to FIG. 1 and FIG. 3 and is not explained herein for sake of brevity. In some embodiments, the one or more users can be enabled to access the data directly from the antenna integrated smart device using the at least one user device.

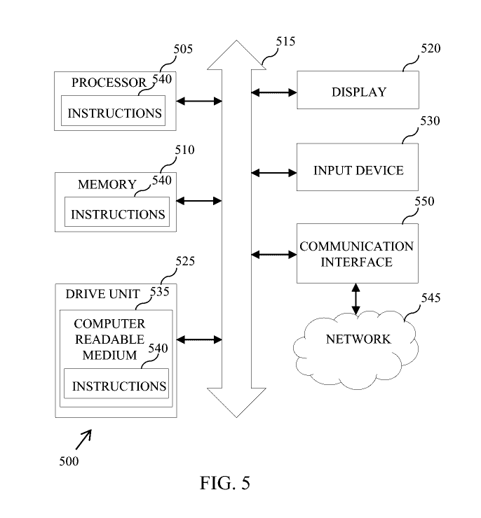

Referring now to FIG. 5, a block diagram of an electronic device 500 is illustrated, which is representative of a hardware environment for practicing the present invention. The electronic device 500 can include a set of instructions that can be executed to cause the electronic device 500 to perform any one or more of the methods disclosed. The electronic device 500 may operate as a standalone device or can be connected, for example using a network, to other electronic devices or peripheral devices.

In a networked deployment of the present invention, the electronic device 500 may operate in the capacity of a user device, for example the user device 180 or the user device 185 of FIG. 1, or the user device 395A or the user device 395B of FIG. 3, in a server-client user network environment, or as a peer electronic device in a peer-to-peer (or distributed) network environment. The electronic device 500 can also be implemented as or incorporated into various devices, such as a personal computer (PC), a tablet PC, a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. Further, while a single electronic device 500 is illustrated, the term “device” shall also be taken to include any collection of systems or sub-systems that individually or jointly execute a set, or multiple sets, of instructions to perform one or more computer functions.

The electronic device 500 can include a processor 505, for example a central processing unit (CPU), a graphics processing unit (GPU), or both. The processor 505 can be a component in a variety of systems. For example, the processor 505 can be part of a standard personal computer or a workstation. The processor 505 can be one or more general processors, digital signal processors, application specific integrated circuits, field programmable gate arrays, servers, networks, digital circuits, analog circuits, combinations thereof, or other now known or later developed devices for analyzing and processing data. The processor 505 can implement a software program, such as code generated manually (for example, programmed).

The electronic device 500 can include a memory 510, such as a memory 510 that can communicate via a bus 515. The memory 510 can include a main memory, a static memory, or a dynamic memory. The memory 510 can include, but is not limited to, computer readable storage media such as various types of volatile and non-volatile storage media, including but not limited to, random access memory, read-only memory, programmable read-only memory, electrically programmable read-only memory, electrically erasable read-only memory, flash memory, magnetic tape or disk, optical media and the like. In one example, the memory 510 includes a cache or random access memory for the processor 505. In alternative examples, the memory 510 is separate from the processor 505, such as a cache memory of a processor, the system memory, or other memory. The memory 510 can be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 510 is operable to store instructions executable by the processor 505. The functions, acts or tasks illustrated in the figures or described can be performed by the programmed processor 505 executing the instructions stored in the memory 510. The functions, acts or tasks are independent of the particular type of instructions set, storage media, processor or processing strategy and can be performed by software, hardware, integrated circuits, firm-ware, micro-code and the like, operating alone or in combination. Likewise, processing strategies can include multiprocessing, multitasking, parallel processing and the like.

As shown, the electronic device 500 can further include a display unit 520, for example a liquid crystal display (LCD), an organic light emitting diode (OLED), a flat panel display, a solid state display, a cathode ray tube (CRT), a projector, a printer or other now known or later developed display device for outputting determined information. The display 520 can act as an interface for a user to see the functioning of the processor 505, or specifically as an interface with the software stored in the memory 510 or in a drive unit 525.

Additionally, the electronic device 500 can include an input device 530 configured to allow the user to interact with any of the components of the electronic device 500. The input device 530 can include a stylus, a number pad, a keyboard, or a cursor control device, for example a mouse, or a joystick, touch screen display, remote control or any other device operative to interact with the electronic device 500.

The electronic device 500 can also include the drive unit 525. The drive unit 525 can include a computer-readable medium 535 in which one or more sets of instructions 540, for example software, can be embedded. Further, the instructions 540 can embody one or more of the methods or logic as described. In a particular example, the instructions 540 can reside completely, or at least partially, within the memory 510 or within the processor 505 during execution by the electronic device 500. The memory 510 and the processor 505 can also include computer-readable media as discussed above.

The present invention contemplates a computer-readable medium that includes instructions 540 or receives and executes the instructions 540 responsive to a propagated signal so that a device connected to a network 545 can communicate voice, video, audio, images or any other data over the network 545. Further, the instructions 545 can be transmitted or received over the network 545 via a communication port or communication interface 550 or using the bus 515. The communication interface 550 can be a part of the processor 505 or can be a separate component. The communication interface 550 can be created in software or can be a physical connection in hardware. The communication interface 550 can be configured to connect with the network 545, external media, the display 520, or any other components in the electronic device 500 or combinations thereof. The connection with the network 545 can be a physical connection, such as a wired Ethernet connection or can be established wirelessly as discussed later. Likewise, the additional connections with other components of the electronic device 500 can be physical connections or can be established wirelessly. The network 545 can alternatively be directly connected to the bus 515.

The network 545 can include wired networks, wireless networks, Ethernet AVB networks, or combinations thereof. The wireless network can include a cellular telephone network, an 802.11, 802.16, 802.20, 802.1Q or WiMax network. Further, the network 545 can be a public network, such as the Internet, a private network, such as an intranet, or combinations thereof, and can utilize a variety of networking protocols now available or later developed including, but not limited to TCP/IP based networking protocols.

In an alternative example, dedicated hardware implementations, such as application specific integrated circuits, programmable logic arrays and other hardware devices, can be constructed to implement various parts of the electronic device 500.

One or more examples described can implement functions using two or more specific interconnected hardware modules or devices with related control and data signals that can be communicated between and through modules, or as portions of an application-specific integrated circuit. Accordingly, the present system encompasses software, firmware, and hardware implementations.

The system described can be implemented by software programs executable by an electronic device. Further, in a non-limited example, implementations can include distributed processing, component/object distributed processing, and parallel processing. Alternatively, virtual electronic device processing can be constructed to implement various parts of the system.

The system is not limited to operation with any particular standards and protocols. For example, standards for Internet and other packet switched network transmission (for example, TCP/IP, UDP/IP, HTML, HTTP) can be used. Such standards are periodically superseded by faster or more efficient equivalents having essentially the same functions. Accordingly, replacement standards and protocols having the same or similar functions as those disclosed are considered equivalents thereof.

Various embodiments disclosed herein provide numerous advantages by providing an antenna communication system and an antenna integrated smart device thereof, and a method of accessing data of the antenna integrated smart device. The antenna integrated device fixed on top of an antenna in a cell site provides an elevated view from the cell site by using an integrated internal camera to help in understanding cell clutter and demographics. External cameras coupled to the antenna integrated device further help in providing security and surveillance of the cell site. The present invention allows storage of the data from multiple such antenna integrated smart devices to generate business analytics and intelligence. The present invention hence reduces capital expenditure of a cellular operator and opens new revenue streams from network infrastructure of the cell site.

While specific language has been used to describe the disclosure, any limitations arising on account of the same are not intended. As would be apparent to a person in the art, various working modifications may be made to the method in order to implement the inventive concept as taught herein.

The figures and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

We claim:

1. An antenna integrated smart device comprising:
an antenna measurement unit configured to determine a plurality of measurements associated with a plurality of antenna parameters of an antenna in a cell site, the plurality of antenna parameters comprising antenna azimuth, antenna tilt, antenna roll, antenna height and antenna geographical coordinates;
a microprocessor coupled to the antenna measurement unit and configured to process the plurality of measurements to determine the plurality of antenna parameters;
a sensor unit coupled to the microprocessor and configured to sense a plurality of environmental conditions around the cell site; and
an integrated internal camera coupled to the microprocessor and configured to capture a first set of images and a first set of videos around the cell site.

2. The antenna integrated smart device as claimed in claim 1 and further comprising:
a data converter module coupled to the microprocessor and configured to convert data into encrypted data and convert the encrypted data into decrypted data;
a wireless module coupled to the microprocessor and configured to exchange the data wirelessly; and
a wired module coupled to the microprocessor and configured to exchange the data through wired connections.

3. The antenna integrated smart device as claimed in claim 2, wherein the antenna measurement unit comprises:
a dual global navigation satellite system (GNSS) receiver coupled to the microprocessor and configured to convert GNSS analog signals to GNSS digital signals, the dual GNSS receiver comprising a first receiver and a second receiver, the first receiver coupled to a first antenna and the second receiver coupled to a second antenna, the first antenna and the second antenna separated by a predetermined distance;
a satellite-based augmentation system (SBAS) receiver coupled to the microprocessor and configured to convert SBAS analog signals to SBAS digital signals; and
an inertial Micro Electro-Mechanical System (MEMS) system coupled to the microprocessor and configured to determine measurement values of the antenna azimuth and the antenna tilt.

4. The antenna integrated smart device as claimed in claim 3, wherein the inertial MEMS system comprises:
an accelerometer configured to measure inertial acceleration of the antenna;
a gyroscope configured to detect changes in one or more rotational attributes of the antenna; and
a magnetometer configured to determine dynamic orientation of the antenna.

5. The antenna integrated smart device as claimed in claim 4, wherein the sensor unit comprises:
a weather sensor module configured to sense a plurality of weather conditions around the cell site; and
a pollution sensor module configured to sense a plurality of pollution levels around the cell site.

6. The antenna integrated smart device as claimed in claim 5, wherein the antenna integrated smart device is coupled to one or more external cameras, the one or more external cameras configured to capture a second set of images and a second set of videos around the cell site.

7. The antenna integrated smart device as claimed in claim 6, wherein the antenna integrated smart device is a master device that communicates with one or more slave devices in the cell site.

8. An antenna communication system comprising:
at least one antenna integrated smart device coupled to an antenna in a cell site to collect data associated with the antenna;
a cloud management server communicably coupled to the at least one antenna integrated smart device to receive and store the data from the at least one antenna integrated smart device, the cloud management server further processing the data to obtain processed data; and
at least one user device communicably coupled to the at least one antenna integrated smart device and the cloud management server to access the data associated with the antenna and the processed data, respectively.

9. The antenna communication system as claimed in claim 8, wherein the at least one antenna integrated smart device comprises:
an antenna measurement unit configured to determine a plurality of measurements associated with a plurality of antenna parameters of the antenna in the cell site, the plurality of antenna parameters comprising antenna azimuth, antenna tilt, antenna roll, antenna height and antenna geographical coordinates;
a microprocessor coupled to the antenna measurement unit and configured to process the plurality of measurements to determine the plurality of antenna parameters;
a sensor unit coupled to the microprocessor and configured to sense a plurality of environmental conditions around the cell site; and
an integrated internal camera coupled to the microprocessor and configured to capture a first set of images and a first set of videos around the cell site.

10. The antenna communication system as claimed in claim 9, wherein the at least one antenna integrated smart device further comprises:
a data converter module coupled to the microprocessor and configured to convert the data into encrypted data and convert the encrypted data into decrypted data;
a wireless module coupled to the microprocessor and configured to exchange the data wirelessly; and
a wired module coupled to the microprocessor and configured to exchange the data through wired connections.

11. The antenna communication system as claimed in claim 10, wherein the antenna measurement unit comprises:
a dual global navigation satellite system (GNSS) receiver coupled to the microprocessor and configured to convert GNSS analog signals to GNSS digital signals, the dual GNSS receiver comprising a first GNSS front-end receiver and a second GNSS front-end receiver, the first GNSS front-end receiver coupled to a first antenna and the second GNSS front-end receiver coupled to a second antenna, the first antenna and the second antenna separated by a predetermined distance;
a satellite-based augmentation system (SBAS) receiver coupled to the microprocessor and configured to convert SBAS analog signals to SBAS digital signals; and
an inertial Micro Electro-Mechanical System (MEMS) system coupled to the microprocessor and configured to determine measurement values of the antenna azimuth and the antenna tilt.

12. The antenna communication system as claimed in claim 11, wherein the inertial MEMS system comprises:
an accelerometer configured to measure inertial acceleration of the antenna;
a gyroscope configured to detect changes in one or more rotational attributes of the antenna; and
a magnetometer configured to determine dynamic orientation of the antenna.

13. The antenna communication system as claimed in claim 12, wherein the sensor unit comprises:
a weather sensor module configured to sense a plurality of weather conditions around the cell site; and
a pollution sensor module configured to sense a plurality of pollution levels around the cell site.

14. The antenna communication system as claimed in claim 13, wherein the antenna integrated smart device is coupled to one or more external cameras, the one or more external cameras configured to capture a second set of images and a second set of videos around the cell site.

15. The antenna communication system as claimed in claim 14, wherein the antenna integrated smart device is a master device that communicates with one or more slave devices in the cell site.

16. A method of accessing data of an antenna integrated smart device implemented in an antenna communication system, the method comprising:
receiving, by a cloud management server, the data associated with the antenna integrated smart device, the antenna integrated smart device being fixed on an antenna in a cell site, the data comprising at least one of a plurality of measurements associated with a plurality of antenna parameters of the antenna, the antenna parameters, a plurality of environmental conditions around the cell site and a plurality of images and videos around the cell site;
processing, by the cloud management server, the data to obtain processed data and to generate business analytics; and
enabling, by the cloud management server, one or more users to access the processed data and the business analytics using at least one user device.

17. The method as claimed in claim 16, wherein the plurality of measurements is determined by an antenna measurement unit of the antenna integrated smart device .

18. The method as claimed in claim 17, wherein the antenna parameters is determined by a microprocessor of the antenna integrated smart device.

19. The method as claimed in claim 18, wherein the plurality of environmental conditions is determined by a sensor unit of the antenna integrated smart device.

20. The method as claimed in claim 19, wherein the plurality of images and videos is determined by at least one of an integrated internal camera of the antenna integrated smart device and one or more external cameras coupled to the antenna integrated smart device.

21. The method as claimed in claim 20 and further comprising:
enabling, by the cloud management server, the one or more users to access the data directly from the antenna integrated smart device using the at least one user device.
